(19) United States
(12) Patent Application Publication
(10) Pub. No.: US 2003/0206053 A1
(43) Pub. Date: Nov. 6, 2003

(54) Carrier recovery for DTV receivers

(76) Inventors: Jingsong Xia, Mundelein, IL (US); Richard W. Citta, Oak Park, IL (US); Scott M. Lopresto, Mount Prospect, IL (US); Wenjun Zhang, Shanghai (CN)

Correspondence Address: Woodard, Emhardt, Moriarty, McNett & Henry LLP, Bank One Center/Tower, 111 Monument Circle, Suite 3700, Indianapolis, IN, 46204-5137, US

(21) Appl. No.: 10/408,053

(22) Filed: Apr. 4, 2003

Related U.S. Application Data
(60) Provisional application No. 60/369,716, filed on Apr. 4, 2002.
(60) Provisional application No. 60/370,326, filed on Apr. 5, 2002.

(51) Int. Cl. H03D 3/02; H03D 3/00; H04N 5/40

(52) U.S. Cl. 329/323; 348/724; 329/341

(57) ABSTRACT

A system and method for carrier recovery independent of a pilot signal uses the frequency and phase information in the upper and lower band edges of a signal to generate a signal for correcting the frequency and phase of the local oscillator. A particular combination of raised-root cosine filters, low-pass filters, multipliers, and adders effectively uses the tails of a received signal in the frequency domain to correct phase errors.

### REFERENCE TO RELATED APPLICATIONS

Priority is claimed to co-pending U.S. Provisional Patent Applications Nos. 60/370,326, filed Apr. 5, 2002, and 60/369,716, filed Apr. 4, 2002. This application is also related to a U.S. Utility Patent Application entitled SYSTEM AND METHOD FOR SYMBOL CLOCK RECOVERY, filed of even date herewith.

### BACKGROUND

Traditionally, local communication was done over wires, as this presented a cost-effective way of ensuring a reliable transfer of information. For long-distance communications, transmission of information over radio waves was needed. Although this was convenient from a hardware standpoint, radio frequency (RF) transmission brought with it problems related to corruption of the information and was often dependent on high-power transmitters to overcome weather conditions, large buildings, and interference from other sources of electromagnetic radiation.

The various modulation techniques that were developed offered different solutions in terms of cost-effectiveness and quality of received signals, but until recently they were still largely analog. Frequency modulation and phase modulation provided a certain immunity to noise, whereas amplitude modulation was more simple to demodulate. More recently, however, with the advent of low-cost mnicrocontrollers and the introduction of domestic mobile telephones and satellite communications, digital modulation has gained in popularity. With digital modulation techniques come all the advantages that traditional microprocessor circuits have over their analog counterparts. Problems in the communications link can be overcome using software. Information can be encrypted, error correction can ensure more confidence in received data, and the use of digital signal processing can reduce the limited bandwidth allocated to each service.

As with traditional analog systems, digital modulation can use amplitude, frequency, or phase modulation with different advantages. As frequency and phase modulation techniques offer more immunity to noise, they are the preferred techniques for the majority of services in use today.

A simple variation from traditional analog frequency modulation can be implemented by applying a digital signal to the modulation input. Thus, the output takes the form of a sine wave at two distinct frequencies. To demodulate this waveform, it is a simple matter of passing the signal through two filters and translating the resultant back into logic levels. Traditionally, this form of digital frequency modulation has been called frequency-shift keying.

Spectrally, digital phase modulation, or phase-shift keying, is very similar to frequency modulation. It involves changing the phase of the transmitted waveform instead of the frequency, these finite phase changes representing digital data. In its simplest form, a phase-modulated waveform can be generated by using the digital data to switch between two signals of equal frequency but opposing phase. If the resultant waveform is multiplied by a sine wave of equal frequency, two components are generated: one cosine waveform of double the received frequency and one frequency-independent term whose amplitude is proportional to the cosine of the phase shift. Thus, filtering out the higher-frequency term yields the original digital data.

Taking the above concept of phase-shift keying a stage further, the number of possible phases can be expanded beyond two. The transmitted “carrier” can undergo changes among any number of phases, and multiplying the received signal by a sine wave of equal frequency, will demodulate the phase shifts into frequency-independent voltage levels.

An example of this technique is quadriphase-shift keying (QPSK). With quadriphase-shift keying, the carrier changes among four phases, and can thus represent any of four values per phase change. Although this may seem insignificant initially, it provides a modulation scheme that enables a carrier to transmit two bits of information per symbol instead of one, thus effectively doubling the data bandwidth of the carrier.

The mathematical proof of how phase-modulated signals, and hence QPSK, are demodulated is shown below.

Euler's relations characterize sine and cosine waves as follows:

$$sin ω t = \frac{{ⅇ}^{j ω t} - {ⅇ}^{- j ω t}}{2 j} cos ω t = \frac{{ⅇ}^{j ω t} + {ⅇ}^{- j ω t}}{2}$$

where j=\sqrt{−1}. Thus, the multiplication of two sine waves of the same frequency and phase is given by:

$$\begin{matrix}{sin}^{2} ω t = \frac{{ⅇ}^{j ω t} - {ⅇ}^{- j ω t}}{2 j} \times \frac{{ⅇ}^{j ω t} - {ⅇ}^{- j ω t}}{2 j} \\ = \frac{{ⅇ}^{2 j ω t} - 2 {ⅇ}^{0} + {ⅇ}^{- 2 j ω t}}{- 4} \\ = - \frac{1}{2} ( \frac{{ⅇ}^{j ( 2 ω ) t} + {ⅇ}^{- j ( 2 ω ) t}}{2} ) + \frac{1}{2} .\end{matrix}$$

Digital receivers implement this operation by mixing an incoming sinusoidal signal with an oscillator output. As the equations above show, the result is a sinusoidal output having a frequency double that of the input, and an amplitude half that of the input, superimposed on a DC offset of half the input amplitude.

Similarly, multiplying sin(ωt) by cos(ωt) gives:

$$\begin{matrix}sin ω t \times cos ω t = \frac{{ⅇ}^{2 j ω t} - {ⅇ}^{- 2 j ω t}}{4 j} \\ = sin 2 ω t .\end{matrix}$$

The result is an output sinusoid having a frequency double that of the input, with no DC offset.

It can be seen that multiplying the cosine wave by any phase-shifted sine wave yields a “demodulated” waveform with an output frequency double that of the input frequency, whose DC offset varies according to the phase shift, φ:

$$\begin{matrix}sin ω t \times sin ( ω t + φ ) = \frac{{ⅇ}^{j ω t} - {ⅇ}^{- j ω t}}{2 j} \times \frac{{ⅇ}^{j ( ω t + φ )} - {ⅇ}^{- j ( ω t + φ )}}{2 j} \\ = \frac{{ⅇ}^{j ( 2 ω t + φ )} - {ⅇ}^{- j ( ω t - ω t - φ )} - {ⅇ}^{j ( ω t + φ - ω t )} + {ⅇ}^{- j ( 2 ω t + φ )}}{- 4} \\ = \frac{cos ( 2 ω t + φ )}{- 2} - \frac{{ⅇ}^{j φ} + {ⅇ}^{- j φ}}{- 4} \\ = \frac{cos ( 2 ω t + φ )}{- 2} + \frac{cos φ}{2} \\ = \frac{cos φ}{2} - \frac{cos ( 2 ω t + φ )}{2}\end{matrix}$$

Thus, a carrier to which a varying phase shift is applied can be demodulated into a varying output voltage by multiplying the carrier with a sinusoidal output from a local oscillator and filtering out the high-frequency component. Unfortunately, the phase shift detection is limited to two quadrants; a phase shift of π/2 cannot be distinguished from a phase shift of −π/2. Therefore, to accurately decode phase shifts present in all four quadrants, the input signal needs to be multiplied by both sinusoidal and cosinusoidal waveforms, the high frequency filtered out, and the data reconstructed. Expanding on the equations above:

$$\begin{matrix}cos ( ω t ) \times sin ( ω t + φ ) = \frac{{ⅇ}^{j ω t} + {ⅇ}^{- j ω t}}{2 } \times \frac{{ⅇ}^{j ( ω t + φ )} + {ⅇ}^{- j ( ω t + φ )}}{2 j} \\ = \frac{{ⅇ}^{j ( 2 ω t + φ )} - {ⅇ}^{j ( - φ )} + {ⅇ}^{j ( φ )} - {ⅇ}^{- j ( 2 ω t + φ )}}{4 j} \\ = \frac{sin ( 2 ω t + φ )}{2} + \frac{sin φ}{2}\end{matrix}$$

However, removing the data from the carrier is not a simple process of low-pass filtering the output of the mixer and reconstructing four voltages back into logic levels. In practice, exactly synchronizing a local oscillator at the receiver with an incoming signal is not easy. If the local oscillator differs in phase from the incoming signal, the signals on the phasor diagram will undergo a phase rotation of a magnitude equal to the phase difference. Moreover, if the phase and frequency of the local oscillator are not fixed with respect to the incoming signal, there will be a continuing rotation on the phasor diagram. Therefore, the output of the front-end demodulator is normally fed into an analog-to-digital (A/D) converter, and any rotation resulting from errors in the phase or frequency of the local oscillator is removed in digital signal processing.

Another problem with extracting the data from the carrier is inter-symbol interference (“ISI”). ISI occurs when pulsed information, such as an amplitude modulated digital transmission, is transmitted over an analog channel, such as, for example, a phone line or an aerial broadcast. The original signal begins as a reasonable approximation of a discrete time sequence, but the received signal is a continuous time signal. The shape of the impulse train is smeared or spread by the transmission into a differentiable signal whose peaks relate to the amplitudes of the original pulses. This signal is read by digital hardware, which periodically samples the received signal.

Each pulse produces a signal that typically approximates a sinc wave. Those skilled in the art will appreciate that a sinc wave is characterized by a series of peaks centered about a central peak, with the amplitude of the peaks monotonically decreasing as the distance from the central peak increases. Similarly, the sinc wave has a series of troughs having a monotonically decreasing amplitude with increasing distance from the central peak. Typically, the period of these peaks is on the order of the sampling rate of the receiving hardware. Therefore, the amplitude at one sampling point in the signal is affected not only by the amplitude of a pulse corresponding to that point in the transmitted signal, but by contributions from pulses corresponding to other bits in the transmission stream. In other words, the portion of a signal created to correspond to one symbol in the transmission stream tends to make unwanted contributions to the portion of the received signal corresponding to the arrival of other symbols in the transmission stream.

This effect can partially be eliminated by proper shaping of the pulses, for example by generating pulses that have zero values at regular intervals corresponding to the sampling rate. However, this requires the receiver to sample at a correct time instant to have the maximum signal power and minimum inter-symbol interference. Since the transmitter and receiver normally have different crystal oscillators, a digital receiver should try its best to synchronize with the transmitter clock. In other words, the receiver must extract the clock information from the received signal and then adjust its A/D timing. This is known as symbol clock recovery.

The Advanced Television Systems Committee (“ATSC”) has selected vestigial sideband (“VSB”) modulation as the transmission standard for digital television (“DTV”). In the ATSC standard, 8 VSB is the standard for terrestrial broadcast, while 16 VSB is used for cable transmission. (The International Telecommunications Union (“ITU”) standard defines five VSB modes: 2, 4, 8, 16, and 8T.)

Typically, 8 VSB uses three supplementary signals for synchronization. First, it uses a low-level RF pilot for carrier acquisition. Second, as shown in FIG. 1, a four-symbol data-segment sync is used once every 832 symbols-that is, once each segment—for synchronizing the data clock in both frequency and phase. (Typically, the four symbols are [1, −1, −1, 1], normalized.) Finally, an 832-symbol data-frame sync is used once every 313 segments for data framing and equalizer training. The data-frame sync also includes information identifying the signal as either 8 VSB, 16 VSB, or one of the other appropriate ITU modes.

The pilot signal has 0.3 dB power. Although the pilot recovery is typically reliable, it can fail under certain circumstances, such as strong, close-in, slow-moving multipathing situations.

Because this kind of multipathing is relatively common in urban environments, where broadcast digital transmission is likely to be desirable, resolving this problem is important to the commercial development of digital television, and to the improvement of other digital transmission systems.

Therefore, a new system and method for carrier recovery is needed that can synchronize with an 8 VSB carrier even when the pilot is totally removed or severely altered, and that operates for a digital transmission having quadrature modulation suitable for use with 8 VSB transmissions. The present invention is directed towards meeting these needs, among others.

### BRIEF DESCRIPTION OF THE DRAWINGS

FIG. 1 is a frequency-domain diagram showing certain features of a typical VSB signal.

FIG. 2 is a block diagram of a circuit for carrier recovery according to the present invention.

FIG. 3 is a diagram of certain features of a VSB signal passing through certain points of the circuit shown in FIG. 2.

### DETAILED DESCRIPTION OF THE PREFERRED EMBODIMENT

For the purposes of promoting an understanding of the principles of the invention, reference will now be made to the embodiment illustrated in the drawings and specific language will be used to describe the same. It will nevertheless be understood that no limitation of the scope of the invention is thereby intended. Alterations and modifications in the illustrated device, and further applications of the principles of the invention as illustrated herein are contemplated as would normally occur to one skilled in the art to which the invention relates.

A carrier recovery system according to the present invention provides more robust capture because it can use both the pilot and the upper and lower band edges. It is therefore more reliable, especially in urban environments, where ghosts are common. A carrier recovery system according to the present invention can even capture when the pilot has been completely destroyed by a perfect null.

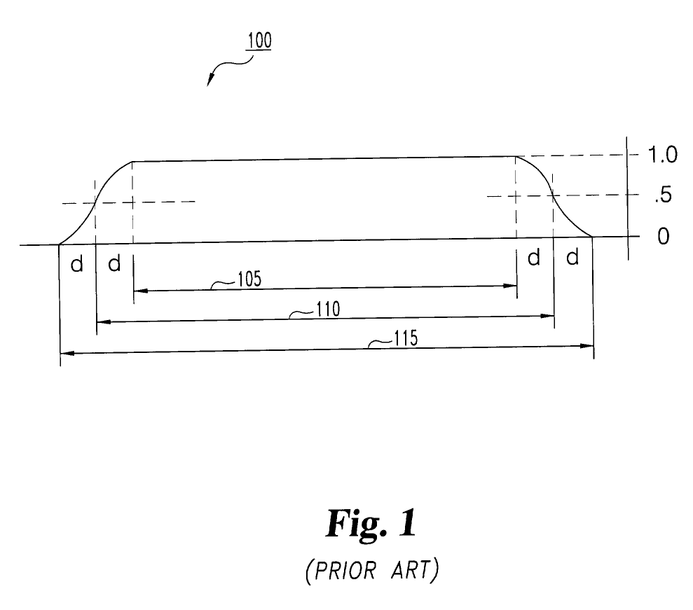

FIG. 1 shows certain features of the spectrum of a VSB signal, shown generally at 100. In this example, the primary portion 110 of the signal 100 is 5.38 MHz wide, including an unattenuated portion 105 within the 3 dB attenuated portion 110. However, the amplitude is not completely damped outside the main frequency domain. A substantial signal exists in this example for an additional 0.31 MHz above and below the primary portion 110 of the signal, this full band being indicated at 115. These “band edges” can be used for carrier recovery, as discussed hereinbelow.

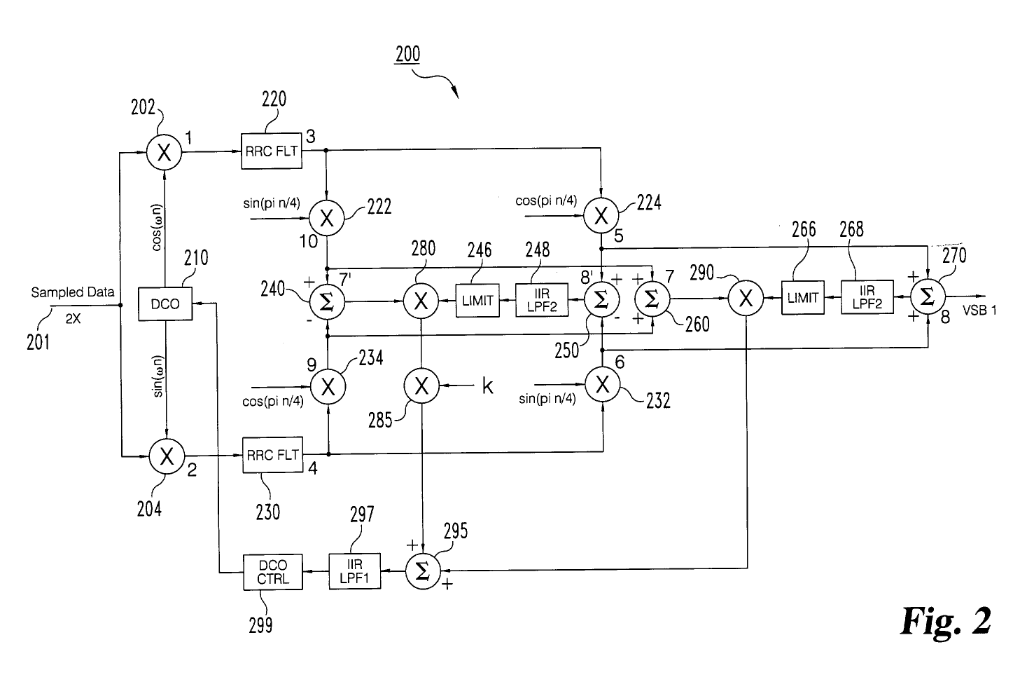

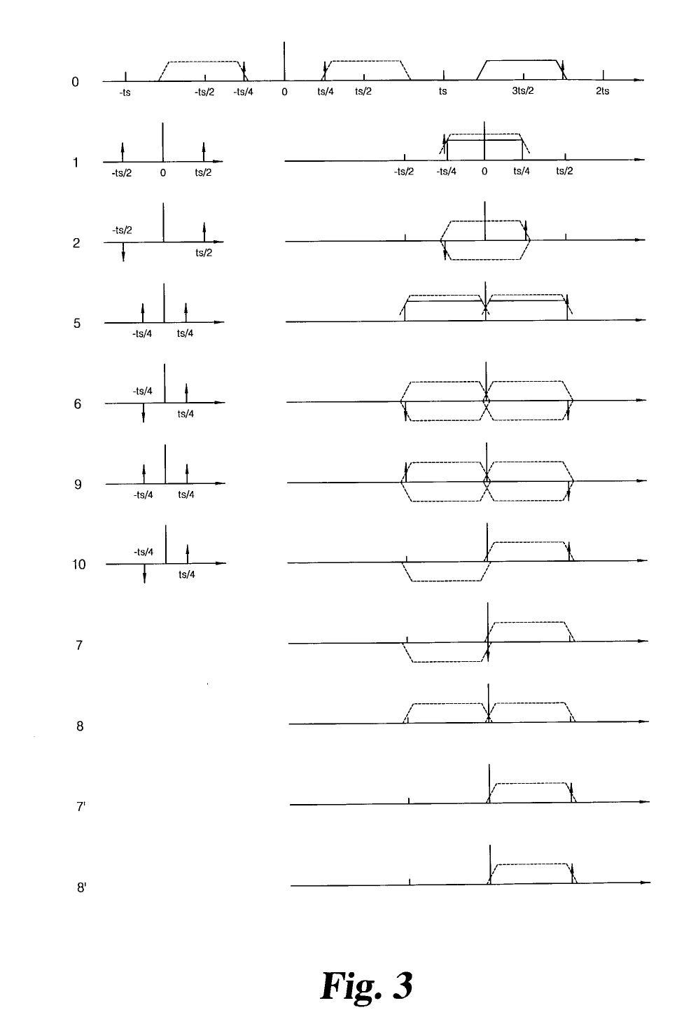

FIG. 2 is a block diagram of a circuit according to the present invention, shown generally at 200, with signals corresponding to certain points being shown in FIG. 3. A signal is input to the circuit 200 at 201 from an A/D converter (not shown) preferably running at twice the symbol rate. It will be appreciated that sampling at twice the symbol rate is sufficient to satisfy the Nyquist condition. This upstream A/D converter can sample its input signal at greater than twice the symbol rate, but increases in the hardware frequency beyond this point result in increases in the hardware cost without a corresponding increase in performance. The circuit 200 comprises a digitally controlled oscillator (“DCO”) 210, which produces two signals: sin(ωn), and cos(ωn), where “n” is the symbol count. A first multiplier 202 multiplies the input signal by the cos(ωn) signal, and a second multiplier 204 multiplies the input signal by the sin(ωn) signal. The outputs from the first and second multipliers 202 and 204 are then passed through first and second root-raised cosine (“RRC”) filters 220 and 230, respectively. The output from the first RRC filter 220 is multiplied by sin(πn/4) at a third multiplier 222, and by cos(πn/4) at a fourth multiplier 224. The output from the second RRC filter 230 is likewise multiplied by sin(πn/4) at a fifth multiplier 232, and by cos(πn/4) at a sixth multiplier 234.

The output from the sixth multiplier 234 is subtracted from the output from the third multiplier 222 by a first accumulator 240 and added to the output from the third multiplier 222 by a third accumulator 260. The output from the fifth multiplier 232 is subtracted from the output from the fourth multiplier 224 by a second accumulator 250 and added to the output from the fourth multiplier 224 by a fourth accumulator 270. The output from the second accumulator 250 is passed through a first low-pass IIR filter 248, preferably having a =3 dB attenuation at 70 kHz to filter out high-frequency components beyond the band edge.

The output from the IIR filter 248 passes through a first limiter 246. The first limiter 246 assigns a value of 1 to any positive input, and a value of −1 to any negative input. (Those skilled in the art will recognize this as a sign ( ) function.) The output from the first limiter 246 is multiplied by the output from the first accumulator 240 using a seventh multiplier 280. It will be appreciated by those skilled in the art that the output from the seventh multiplier 280 has been multiplied by two RRC filters, so that the signal has been effectively multiplied by a plain raised cosine filter overall. Thus, the output from the seventh multiplier 280 represents the frequency and phase correction information obtained from the lower band edge.

The output from the fourth accumulator 270 is passed through a second low-pass IIR filter 268, preferably having a −3 dB attenuation at 70 kHz to filter out high-frequency components beyond the band edge. The output from the filter 268 passes through a second limiter 266. Like the first limiter 246, the second limiter 266 assigns a value of 1 to any positive input, and a value of −1 to any negative input. The output from the second limiter is multiplied by the output from the third accumulator 260 using an eighth multiplier 290. It will be appreciated that the output from the eighth multiplier 290 represents the frequency and phase correction information obtained from the upper band edge.

The output from the seventh multiplier 280 is then multiplied by a weight factor “k” using a ninth multiplier 285. The output from the eighth multiplier 290 is subtracted from the output from the ninth multiplier 285 using a fifth accumulator 295. The output from the fifth accumulator 295 is then passed through a third low-pass IIR filter 297 to generate the signal provide to the DCO controller 299, which completes the feedback loop that provides carrier recovery.

Those skilled in the art will recognize that the lower band edge of a VSB signal contains the pilot signal. This is the reason for the weight factor applied by the ninth multiplier 285. Typically, when k is about 0.3 the upper and lower band edge contributions will be properly balanced.

Variations in the implementation of the invention will occur to those of skill in the art. For example, some or all of the generation and calculation of signals can be performed by application-specific or general-purpose integrated circuits, or by discrete components, or in software.

While the invention has been illustrated and described in detail in the drawings and foregoing description, the same is to be considered as illustrative and not restrictive in character, it being understood that only the preferred embodiment has been shown and described and that all changes and modifications that come within the spirit of the invention are desired to be protected.

What is claimed is:

1. A method of demodulating a received signal, comprising:
receiving a stream of digital data comprising a sequence of data elements sₜ representing the received signal;
using a digitally controlled oscillator to generate
a sequence of data elements representative of sin(2πnt/f), and
a sequence of data elements representative of cos(2πnt/f);
determining aₜ=sin(πt/4) RRC(sₜ cos(2πt/f));
determining b₁=cos(πt/4) RRC(sₜ cos(2πt/f));
determining cₜ=cos(πt/4) RRC(sₜ sin(2πt/f));
determining dₜ=sin(πt/4) RRC(sₜ sin(2πt/f)); and
providing a first output signal
cₜ=L₃(k(aₜ−cₜ)(sign(L₁(b_{t-d}ₜ)))−(aₜ+cₜ)(sign(L₂(bₜ+dₜ)));
wherein
RRC is a root-raised cosine filter; and
L₁, L₂, and L₃ are infinite impulse response, low-pass filters having a predetermined pass band:

2. The method of claim 1, further comprising adjusting the symbol clock responsively to the first output signal.

3. The method of claim 1, further comprising providing a second output signal vₜ=bₜ+dₜ.

4. A system for processing a received signal having an expected center frequency at 0, a 0 dB bandwidth b₀, and a −3 dB bandwidth b₃, comprising:
a digitally controlled oscillator for generating at least one sinusoidal signal for mixing with the received signal;
a digital signal processing means for generating a control signal for the oscillator as a function of the frequency-domain components of the received signal having frequencies f₁ and fₕ, such that
(b₀/2)−b₃<f₁<−(b₀/2), and
(b₀/2)<fₕ<b₃−(b₀/2).

5. A method of demodulating a received signal, comprising:
receiving a stream of digital data comprising a sequence of data elements representing the received signal sampled according to a clock, where the clock is subject to adjustment in frequency and/or phase by a clock adjustment signal;
multiplying the sequence of data elements by a digital cosine wave of the target frequency, and passing the result through a first raised-root cosine filter to yield a first intermediate sequence;
multiplying the sequence of data elements by a digital sine wave of the target frequency, and passing the result through a first raised-root cosine filter to yield a second intermediate sequence;
multiplying the first intermediate sequence by a digital sine wave of one-quarter the target frequency to yield a third intermediate sequence;
multiplying the first intermediate sequence by a digital cosine wave of one-quarter the target frequency to yield a fourth intermediate sequence;
multiplying the second intermediate sequence by a digital cosine wave of one-quarter the target frequency to yield a fifth intermediate sequence;
multiplying the second intermediate sequence by a digital sine wave of one-quarter the target frequency to yield a sixth intermediate sequence;
subtracting the fifth intermediate sequence from the third intermediate sequence to yield a seventh intermediate sequence;
subtracting the sixth intermediate sequence from the fourth intermediate sequence to yield an eighth intermediate sequence;
obtaining a ninth intermediate sequence as the product of a predetermined constant k;
the seventh intermediate sequence; and
the sign of the result of passing the eighth intermediate sequence through an infinite-impulse-response, low-pass filter;
adding the third intermediate sequence and the fifth intermediate sequence to yield a tenth intermediate sequence;
adding the fourth intermediate sequence and the sixth intermediate sequence to yield an eleventh intermediate sequence;
obtaining a twelfth intermediate sequence as the product of the tenth intermediate sequence; and
the sign of the result of passing the eleventh intermediate sequence through an infinite-impulse-response, low-pass filter;
adding the ninth intermediate sequence and the twelfth intermediate sequence to yield a thirteenth intermediate sequence; and
adjusting the clock as a function of the result of passing the thirteenth intermediate sequence through an infinite-impulse-response, low-pass filter.
